(19) United States
(12) Patent Application Publication
(10) Pub. No.: US 2025/0057020 A1
(43) Pub. Date: Feb. 13, 2025

(54) DISPLAY APPARATUS

(71) Applicant: Samsung Display Co., Ltd., Yongin-Si (KR)

(72) Inventors: Jaeik Lim, Yongin-si (KR); Seongjun Lee, Yongin-si (KR)

(21) Appl. No.: 18/733,852

(22) Filed: Jun. 5, 2024

(30) Foreign Application Priority Data
Aug. 11, 2023 (KR) 10-2023-0105631

(51) Int. Cl. H10K 59/80; H10K 59/40

(52) U.S. Cl. CPC H10K 59/879; H10K 59/40; H10K 59/873

(57) ABSTRACT

Provided is a display apparatus including a display element including a light-emitter emitting light, a first refractive layer disposed over the display element, and a second refractive layer covering the first refractive layer, wherein an edge of the light-emitter includes a first light-emitting edge extending in a first direction, an edge of the first refractive layer includes a first refractive edge corresponding to the first light-emitting edge, wherein the first refractive edge includes a first portion forming a first angle with the first light-emitting edge on a plane, and a second portion forming a second angle greater than the first angle with the first light-emitting edge on the plane.

### CROSS-REFERENCE TO RELATED APPLICATION

This application is based on and claims priority under 35 U.S.C. § 119 to Korean Patent Application No. 10-2023-0105631, filed on Aug. 11, 2023, in the Korean Intellectual Property Office, the disclosure of which is incorporated by reference herein in its entirety.

### BACKGROUND

### 1. Field

One or more embodiments relate to a display apparatus, and more particularly, to a display apparatus that has excellent light emission efficiency.

### 2. Description of the Related Art

As the demand for display apparatuses expands, the need for display apparatuses that may be used for various purposes is also increasing. Along with this trend, display apparatuses tend to gradually become larger or thinner, and the need for a display apparatus that provide larger and thinner displays while having accurate and vivid colors is also increasing.

### SUMMARY

One or more embodiments include a display apparatus in which the efficiency of light extracted from a display apparatus is increased. However, the one or more embodiments are only examples, and the scope of the present disclosure is not limited thereto.

Additional aspects will be set forth in part in the description which follows and, in part, will be apparent from the description, or may be learned by practice of the presented embodiments of the disclosure.

According to one or more embodiments, provided is a display apparatus including a display element including a light-emitter emitting light, a first refractive layer disposed over the display element, and a second refractive layer covering the first refractive layer. An edge of the light-emitter includes a first light-emitting edge extending in a first direction. An edge of the first refractive layer includes a first refractive edge corresponding to the first light-emitting edge. The first refractive edge includes a first portion forming a first angle with the first light-emitting edge on a plane, and a second portion forming a second angle greater than the first angle with the first light-emitting edge on the plane.

According to one or more embodiments, the edge of the first refractive layer surrounds the light-emitter.

According to one or more embodiments, the first light-emitting edge and the first portion may be parallel on the plane.

According to one or more embodiments, the second angle is of at least about 20° but not more than about 70° on the plane.

According to one or more embodiments, the second portion on the plane may be shaped to protrude in a second direction intersecting the first direction.

According to one or more embodiments, the first refractive edge may be in a form of an alternating connection of the first portion and the second portion.

According to one or more embodiments, the second portion may have a length in the first direction of at least about 0.2 times but not more than about 4 times a length in the first direction of the first portion.

According to one or more embodiments, the first refractive layer may overlap at least partially with the light-emitter.

According to one or more embodiments, a refractive index of the first refractive layer may be greater than a refractive index of the second refractive layer.

According to one or more embodiments, a portion of the edge of the first refractive layer on the plane may overlap a portion of the edge of the light-emitter.

According to one or more embodiments, the second portion on the plane may be curved.

According to one or more embodiments, the first refractive layer may have a thickness of at least about 1.5 μm but not more than about 5 μm.

According to one or more embodiments, the edge of the first refractive layer may be provided with an incline forming an angle of at least about 30° but not more than about 85° with a layer arranged below.

According to one or more embodiments, the apparatus may further include an encapsulation layer between the display element and the first refractive layer.

According to one or more embodiments, the apparatus may further include an input detection layer; disposed over the encapsulation layer and including a conductive layer and a touch insulation layer covering the conductive layer. The touch insulation layer and the first refractive layer may be arranged in a same layer.

According to another aspect of the disclosure, provided is a display apparatus including a display element including a light-emitter that emits light, an encapsulation layer covering the display element, a first refractive layer disposed over the encapsulation layer, the first refractive layer having an edge surrounding the light-emitter, and a second refractive layer covering the first refractive layer. The edge of the first refractive layer includes a first portion parallel to an edge of the light-emitter on a plane and a second portion protruding in a direction perpendicular to the edge of the light-emitter on the plane.

According to one or more embodiments, a refractive index of the first refractive layer may be at least 0.04 greater than a refractive index of the second refractive layer.

According to one or more embodiments, the edge of the first refractive layer may be in the form of an alternating connection of the first portion and the second portion.

According to one or more embodiments, the second portion may be curved on the plane.

According to one or more embodiments, the edge of the first refractive layer may be provided with an incline forming an angle of at least about 30° but not more than about 85° with a layer arranged below.

Other aspects and features other than those described above will become apparent from the detailed description, claims and drawings for carrying out the disclosure below.

### BRIEF DESCRIPTION OF THE DRAWINGS

The above and other aspects and features of certain embodiments of the disclosure will be more apparent from the following description taken in conjunction with the accompanying drawings.

FIG. 1 is a perspective view schematically illustrating a display apparatus according to an embodiment.

FIG. 2 is a cross-sectional view schematically illustrating the display apparatus according to an embodiment, being a cross-sectional view along line I-I′ of FIG. 1.

FIG. 3 is a top view schematically illustrating the display apparatus according to an embodiment.

FIG. 4A and FIG. 4B are pixel equivalent circuit schematics that may be included in the display apparatus according to an embodiment.

FIG. 5 is a partial top view schematically illustrating an arrangement of pixels according to an embodiment.

FIG. 6 is a cross-sectional view schematically illustrating the display apparatus according to an embodiment, being a cross-sectional view along line II-II′ of FIG. 5.

FIG. 7 is a top view schematically illustrating the arrangement of light-emitters in a display area according to an embodiment.

FIG. 8 is a cross-sectional view schematically illustrating the display apparatus according to an embodiment, being a cross-sectional view along line III-III′ of FIG. 7.

FIG. 9 is a top view schematically illustrating the placement relationship of a light-emitter and a first refractive layer according to an embodiment.

FIG. 10 is a top view schematically illustrating the light-emitter and the first refractive layer according to an embodiment.

FIG. 11A and FIG. 11B are top views schematically illustrating the light-emitter and the first refractive layer according to an embodiment.

FIG. 12 is a top view schematically illustrating the light-emitter and the first refractive layer according to an embodiment.

FIG. 13A and FIG. 13B are top views schematically illustrating the light-emitter and the first refractive layer according to an embodiment.

FIG. 14 is a top view schematically illustrating the light-emitter and the first refractive layer according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Since the present disclosure may be modified in various ways and may have many embodiments, specific embodiments will be illustrated in the drawings and described in detail in the detailed description. The effects and features of the disclosure, and methods of achieving them, will become clear with reference to the embodiments described below in detail together with the drawings. However, the disclosure is not limited to the embodiments described herein and may be implemented in various forms.

Hereinafter, embodiments will be described in detail with reference to the accompanying drawings, and when describing with reference to the drawings, the same or corresponding components are given the same reference numerals, and duplicate descriptions thereof will be omitted.

In the following embodiments, the terms first, second, etc. are not intended to be limiting, however are used to distinguish one component from another component.

In the following embodiments, the singular expression includes the plural unless the context clearly indicates otherwise.

In the following embodiments, the terms including or that has, etc. are intended to imply the presence of the recited features or components and do not preclude the possibility of the addition of one or more other features or components.

In the following embodiments, when a portion of a film, area, component, etc. is said to be over or on the upper portion of another portion, this includes not only when it is directly on the upper portion of another portion, however also when there are other films, areas, components, etc. arranged therebetween.

In the drawings, components may be exaggerated or reduced in size for ease of illustration. For example, the size and thickness of each configuration shown in the drawings are arbitrary for ease of description and the disclosure is not necessarily limited to those shown.

In some embodiments, a particular sequence of processes may be performed in a different order than that described. For example, two processes described in succession may be performed substantially simultaneously, or may be performed in the opposite order from the order described.

As used herein, “A and/or B” refers to A, B, or both A and B. Further, “at least one of A and B” represents the case of A, B, or A and B.

In the following embodiments, references to films, areas, components, etc. being connected include direct connections between films, areas, components, and/or indirect connections between films, areas, and components, with other films, areas, and components, arranged between them. For example, as used herein, when referring to films, areas, components, etc. as being electrically connected herein, it refers to films, areas, components, etc. being directly electrically connected, and/or indirectly electrically connected with other films, areas, components, etc. arranged therebetween.

The terms x-axis, y-axis, and z-axis are not limited to, but may be interpreted in a broad sense to include, three axes in a Cartesian coordinate system. For example, the x-axis, y-axis, and z-axis may be orthogonal to each other, however may also refer to different directions that are not orthogonal to each other.

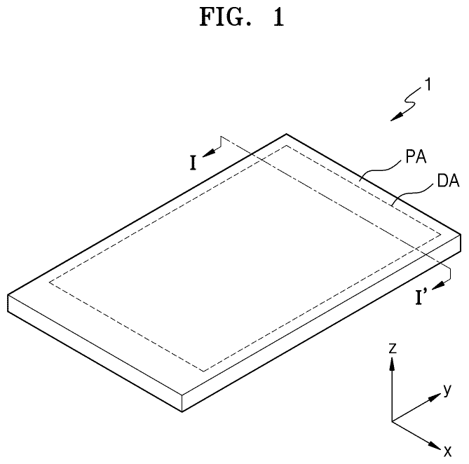

FIG. 1 is a perspective view schematically illustrating a display apparatus 1 according to an embodiment.

Referring to FIG. 1, the display apparatus 1 according to an embodiment may include a display area DA and a peripheral area PA. The peripheral area PA may be arranged to surround the display area DA on the periphery of the display area DA. The peripheral area PA may contain various wiring and a drive circuit portion to transmit electrical signals to be applied to the display area DA. The display apparatus 1 may provide a certain image using light emitted by a plurality of pixels arranged in the display area DA. Although not illustrated, the display apparatus 1 may be bent, including a bending area in a portion of the peripheral area PA.

The display apparatus 1 may be a display apparatus such as an organic light-emitting display, an inorganic light-emitting display or inorganic electroluminescent (EL) display, or a quantum dot light-emitting display. Hereinafter, the organic light-emitting display will be described as an example. The display apparatus 1 may be implemented in various types of electronic devices, such as a mobile phone, a laptop, or a smart watch.

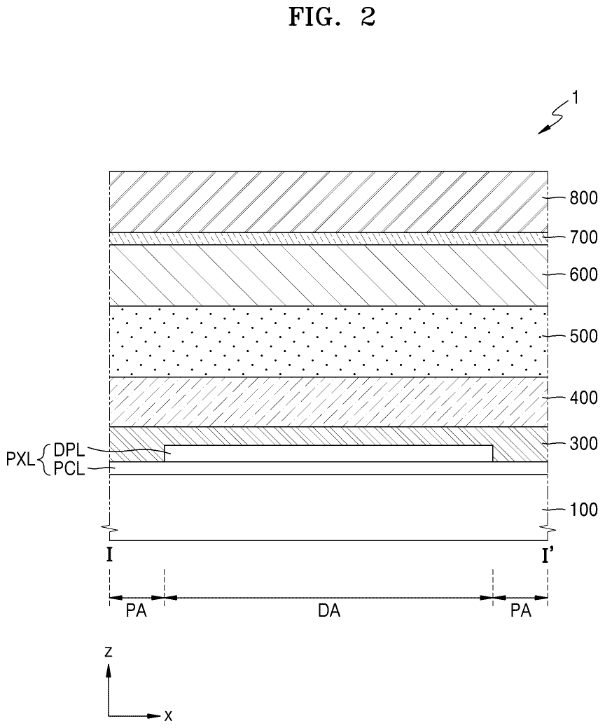

FIG. 2 is a cross-sectional view schematically illustrating the display apparatus 1 according to an embodiment. More specifically, FIG. 2 corresponds to a cross-sectional view taken along line I-I′ of FIG. 1.

Referring to FIG. 2, the display apparatus 1 may further include a substrate 100 sequentially stacked in the thickness direction (z-direction), a pixel layer PXL on the substrate 100, an encapsulation layer 300 sealing the pixel layer PXL, an input detection layer 400 on the encapsulation layer 300, a refractive layer 500, a polarization layer 600 on the refractive layer 500, an adhesive layer 700, and a window 800.

The substrate 100 may include a glass material, or may include a polymer resin. For example, the substrate 100 may include a glass material containing silicon oxide (SiO₂) as a main component, or may include various materials with flexible or bendable properties, for example, resin such as reinforced plastic. Although not illustrated, the substrate 100 may be bent, including a bending area in a portion of the peripheral area PA.

A pixel layer PXL may be disposed on the substrate 100. The pixel layer PXL may include a display element layer DPL including display elements arranged in each pixel, and a pixel circuit layer PCL including pixel circuits and insulation layers arranged in each pixel. The display element layer DPL may be disposed on the upper layer of the pixel circuit layer PCL, and a plurality of insulation layers may be arranged between the pixel circuit and the display element. Some wiring and insulation layers of the pixel circuit layer PCL may extend to the peripheral area PA.

The encapsulation layer 300 may be a thin-film encapsulation layer. The thin-film encapsulation layer may include at least one inorganic encapsulation layer and at least one organic encapsulation layer. When the display apparatus 1 is provided with the substrate 100 including a polymer resin and the encapsulation layer 300 of a thin-film encapsulation layer including an inorganic encapsulation layer and an organic encapsulation layer, the flexibility of the display apparatus 1 may be improved.

The input detection layer 400 may acquire coordinate information according to an external input, for example a touch event of an object such as a finger or a stylus pen.

The refractive layer 500 may adjust the path of light emitted by the display elements of the display element layer DPL and improve the light emission efficiency of the display apparatus 1. As will be described below, the refractive layer 500 may increase the light extraction efficiency of the display apparatus 1 by changing the path of light emitted from the display element.

The polarization layer 600 may transmit light emitted from the display elements of the display element layer DPL only to light oscillating in the same direction as the polarization axis, and may absorb or reflect light oscillating in other directions. The polarization layer 600 may include a retarder and/or a polarizer. Additionally, the polarization layer 600 may include a black matrix and/or a color filter. Although not illustrated, the refractive layer 500 and the polarization layer 600 may be adhered by an adhesive, such as an optically clear adhesive (OCA).

The window 800 is disposed over the polarization layer 600, between which the adhesive layer 700, such as the optically clear adhesive (OCA), may be arranged.

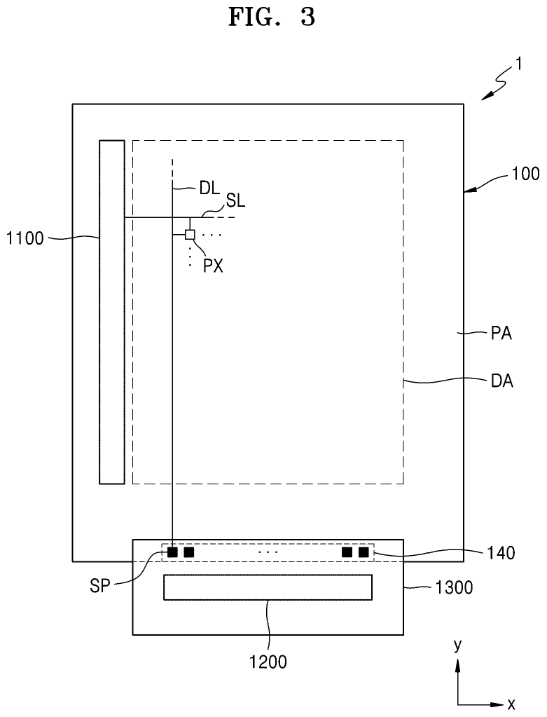

FIG. 3 is a top view schematically illustrating the display apparatus 1 according to an embodiment.

Referring to FIG. 3, the substrate 100 may include the display area DA and the peripheral area PA. The peripheral area PA may be located on the periphery of the display area DA and may surround the display area DA.

The display area DA on the upper portion of the substrate 100 may be provided with a plurality of pixels PX arranged in a first direction (x-direction, row direction) and a second direction (y-direction, column direction) in a certain pattern.

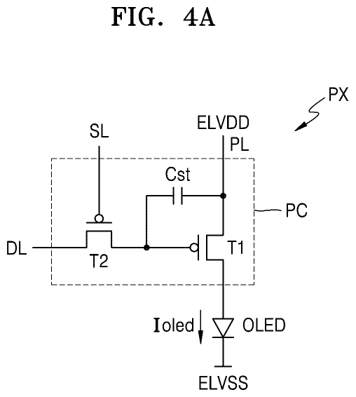

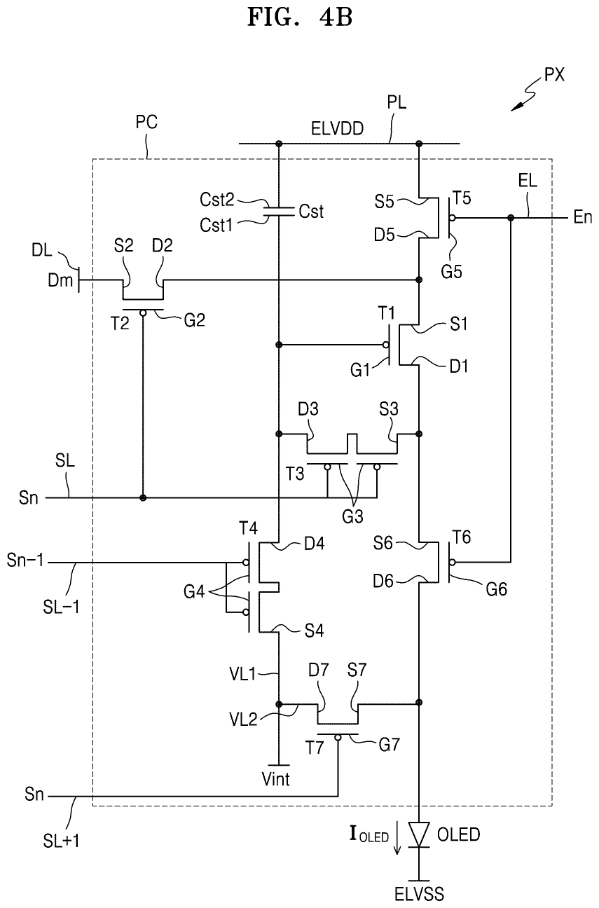

In the peripheral area PA on the upper portion of the substrate 100, a scan driver 1100 providing scan signals to each pixel PX, a data driver 1200 providing data signals to each pixel PX, and main power wiring (not shown) for providing a first power supply voltage ELVDD (see FIG. 4A and FIG. 4B) and a second power supply voltage ELVSS (see FIG. 4A and FIG. 4B), etc. may be arranged. A pad portion 140, on which a plurality of signal pads SP connected to data lines DL, may be located in the peripheral area PA of the upper portion of the substrate 100.

The scan driver 1100 may include an oxide semiconductor TFT gate driver circuit (OSG) or an amorphous silicon TFT gate driver circuit (ASG). While FIG. 3 depicts an example where the scan driver 1100 is arranged adjacent to one side of the substrate 100, according to an embodiment, the scan driver 1100 may be arranged adjacent to each of two opposing sides of the substrate 100.

FIG. 3 illustrates a chip-on-film (COF) approach in which a data driver 1200 is disposed on a film 1300 electrically connected to a set of the signal pads SP disposed over the substrate 100. According to some embodiments, the data driver 1200 may be disposed directly on the substrate 100 using a Chip On Glass (COG) or Chip On Plastic (COP) method. The data driver 1200 may be electrically connected to a flexible Printed circuit board (FPCB).

FIG. 4A and FIG. 4B are pixel equivalent circuit schematics that may be included in a display apparatus according to an embodiment.

Referring to FIG. 4A, a pixel PX includes a pixel circuit PC connected to a scan line SL and a data line DL, and a display element connected to the pixel circuit PC. The pixel circuit PC may include a thin-film transistor and a storage capacitor, and the display element may include an organic light-emitting diode OLED.

The pixel circuit PC may include a drive thin-film transistor T1, a switching thin-film transistor T2, and a storage capacitor Cst. Each pixel PX may emit light, for example, red, green, blue, or white, by the organic light-emitting diode OLED.

The switching thin-film transistor T2 may each be connected to the scan line SL and the data line DL. The switching thin-film transistor T2 may transmit the data signal input from the data line DL to the drive thin-film transistor T1 according to the scan signal input from the scan line SL. The storage capacitor Cst is connected to the switching thin-film transistor T2 and a drive voltage line PL, and may store a voltage corresponding to the difference between the voltage corresponding to the data signal received from the switching thin-film transistor T2 and a first power supply voltage ELVDD supplied to the drive voltage line PL.

The drive thin-film transistor T1 may each be connected to the drive voltage line PL and the storage capacitor Cst. The drive thin-film transistor T1 may control the drive current I_{OLED} flowing through the organic light-emitting diode OLED from the drive voltage line PL in response to the voltage value stored in the storage capacitor Cst.

The organic light emitting diode OLED may emit light that has a certain luminance by the drive current I_{OLED}. The organic light emitting diode OLED may include a pixel electrode, a counter electrode, and an intermediate layer including an emission layer between the pixel electrode and the counter electrode. The counter electrode of the organic light emitting diode OLED may be supplied with a second power supply voltage ELVSS.

FIG. 4A illustrates a pixel circuit PC including two thin-film transistors T1, T2 and one storage capacitor Cst, but the disclosure is not limited thereto. The number of thin-film transistors and the number of storage capacitors may be variously changed according to the design of the pixel circuit PC.

As another example, referring to FIG. 4B, one pixel PX may include a pixel circuit PC and an organic light-emitting diode OLED electrically connected to the pixel circuit PC.

The pixel circuit PC may include a plurality of thin-film transistors T1 to T7 and the storage capacitor Cst, as shown in FIG. 4B. The thin-film transistors T1 to T7 and the storage capacitor Cst may be connected to signal lines SL, SL−1, SL+1, EL, DL, a first initialization voltage line VL1, a second initialization voltage line VL2, and a drive voltage line PL.

The signal lines SL, SL−1, SL+1, EL, DL may include a scan line SL configured to transmit a scan signal Sn, a previous scan line SL−1 configured to transmit a previous scan signal Sn−1 to a first initialization thin-film transistor T4, and a later scan line SL+1 configured to transmit a scan signal Sn to a second initialization thin-film transistor T7, a light emission control line EL that transmits an light emission control signal En to each of an operation control thin-film transistor T5 and a light emission control thin-film transistor T6, and a data line DL that intersects the scan line SL and transmits a data signal Dm. The drive voltage line PL may be configured to deliver a drive voltage ELVDD to the drive thin-film transistor T1, the first initialization voltage line VL1 may be configured to deliver an initialization voltage Vint to the first initialization thin-film transistor T4, and the second initialization voltage line VL2 may be configured to deliver the initialization voltage Vint to the second initialization thin-film transistor T7.

A drive gate electrode G1 of the drive thin-film transistor T1 is connected to a lower electrode Cst1 of the storage capacitor Cst, a drive source electrode S1 of the drive thin-film transistor T1 is connected to the drive voltage line PL by the operation control thin-film transistor T5, and a drive drain electrode D1 of the drive thin-film transistor T1 is electrically connected to the pixel electrode of the organic light-emitting diode OLED by the light emission control thin-film transistor T6. The drive thin-film transistor T1 receives the data signal Dm according to the switching operation of the switching thin-film transistor T2 and may supply the drive current I_{OLED} to the organic light-emitting diode OLED.

The switching gate electrode G2 of the switching thin-film transistor T2 is connected to the scan line SL, a switching source electrode S2 of the switching thin-film transistor T2 is connected to the data line DL, and a switching drain electrode D2 of the switching thin-film transistor T2 is connected to the drive source electrode S1 of the drive thin-film transistor T1 and may be connected to the drive voltage line PL by the operation control thin-film transistor T5. The switching thin-film transistor T2 is turned on according to the scan signal Sn received by the scan line SL, and may perform a switching operation to deliver the data signal Dm transmitted by the data line DL to the drive source electrode S1 of the drive thin-film transistor T1.

A compensation gate electrode G3 of a compensation thin-film transistor T3 is connected to the scan line SL, a compensation source electrode S3 of the compensation thin-film transistor T3 is connected to the drive drain electrode D1 of the drive thin-film transistor T1 and is also connected to the pixel electrode of the organic light-emitting diode OLED by the light emission control thin-film transistor T6, and a compensation drain electrode D3 of the compensation thin-film transistor T3 is connected to each the lower electrode Cst1 of the storage capacitor Cst, a first initialization drain electrode D4 of the first initialization thin-film transistor T4, and the drive gate electrode G1 of the drive thin-film transistor T1. The compensation thin-film transistor T3 is turned on according to the scan signal Sn received by the scan line SL to electrically connect the drive gate electrode G1 and the drive drain electrode D1 of the drive thin-film transistor T1 to diode connect the drive thin-film transistor T1.

A first initialization gate electrode G4 of the first initialization thin-film transistor T4 is connected to the previous scan line SL−1, a first initialization source electrode S4 of the first initialization thin-film transistor T4 is connected to the first initialization voltage line VL1, and the first initialization drain electrode D4 of the first initialization thin-film transistor T4 is connected to each the lower electrode Cst1 of the storage capacitor Cst, the compensation drain electrode D3 of the compensation thin-film transistor T3, and the drive gate electrode G1 of the drive thin-film transistor T1. The first initialization thin-film transistor T4 is turned on according to the previous scan signal Sn−1 received by the previous scan line SL−1, and may perform an initialization operation to initialize the voltage of the drive gate electrode G1 of the drive thin-film transistor T1 by delivering an initialization voltage Vint to the drive gate electrode G1 of the drive thin-film transistor T1.

An operation control gate electrode G5 of the operation control thin-film transistor T5 is connected to the light emission control line EL, an operation control source electrode S5 of the operation control thin-film transistor T5 is connected to the drive voltage line PL, and an operation control drain electrode D5 of the operation control thin-film transistor T5 is connected to each the drive source electrode S1 of the drive thin-film transistor T1 and the switching drain electrode D2 of the switching thin-film transistor T2.

A light emission control gate electrode G6 of the light emission control thin-film transistor T6 is connected to the light emission control line EL, a light emission control source electrode S6 of the light emission control thin-film transistor T6 is connected to each the drive drain electrode D1 of the drive thin-film transistor T1 and the compensation source electrode S3 of the compensation thin-film transistor T3, and a light emission control drain electrode D6 of the light emission control thin-film transistor T6 is electrically connected to each of a second initialization source electrode S7 of the second initialization thin-film transistor T7 and the pixel electrode of the organic light-emitting diode OLED.

The operation control thin-film transistor T5 and the light emission control thin-film transistor T6 may be simultaneously turned on according to the light emission control signal En received by the light emission control line EL, so that the drive voltage ELVDD is delivered to the organic light-emitting diode OLED and the drive current I_{OLED} flows to the organic light-emitting diode OLED.

A second initialization gate electrode G7 of the second initialization thin-film transistor T7 is connected to a subsequent scan line SL+1, the second initialization source electrode S7 of the second initialization thin-film transistor T7 is connected to the light emission control drain electrode D6 of the light emission control thin-film transistor T6 and the pixel electrode of the organic light-emitting diode OLED, and a second initialization drain electrode D7 of the second initialization thin-film transistor T7 is connected to the second initialization voltage line VL2.

Meanwhile, the scan line SL and the subsequent scan line SL+1 are electrically connected to each other, so that the same scan signal Sn may be applied to the scan line SL and the subsequent scan line SL+1. Therefore, the second initialization thin-film transistor T7 may be turned on according to the scan signal Sn received through the subsequent scan line SL+1 and perform an operation to initialize the pixel electrode of the organic light-emitting diode OLED.

The upper electrode Cst2 of the storage capacitor Cst is connected to the drive voltage line PL, and a common electrode of the organic light-emitting diode OLED is connected to the common voltage ELVSS. Accordingly, the organic light-emitting diode OLED receives the drive current I_{OLED} from the drive thin-film transistor T1 and may emit light to display an image.

In FIG. 4B, the compensation thin-film transistor T3 and the first initialization thin-film transistor T4 are illustrated as having dual gate electrodes, but the compensation thin-film transistor T3 and the first initialization thin-film transistor T4 may have a single gate electrode.

Additionally, although FIG. 4B illustrates a structure for one pixel circuit PC, a plurality of pixels PX that has the same pixel circuit PC may be arranged to form a plurality of rows, wherein the first initialization voltage line VL1, the previous scan line SL−1, the second initialization voltage line VL2, and the subsequent scan line SL+1 may be shared by neighboring pixels.

For example, the first initialization voltage line VL1 and the previous scan line SL−1 may be electrically connected to a second initialization thin-film transistor of another pixel circuit PC arranged along the second direction (y-direction). Thus, a previous scan signal applied to the previous scan line SL−1 may be transmitted as a subsequent scan signal to the second initialization thin-film transistor of the other pixel circuit PC. Similarly, the second initialization voltage line VL2 and the subsequent scan line SL+1 may be electrically connected to the first initialization thin-film transistor of another pixel circuit PC arranged adjacent along the second direction (y-direction) relative to the drawing to transmit the previous scan signal and the initialization voltage.

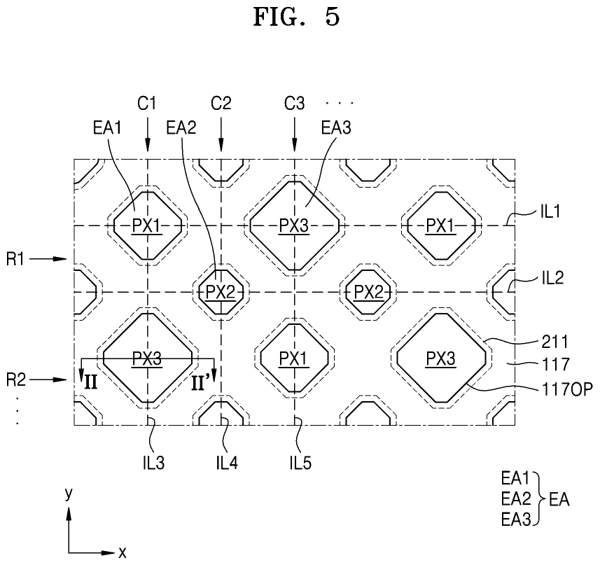

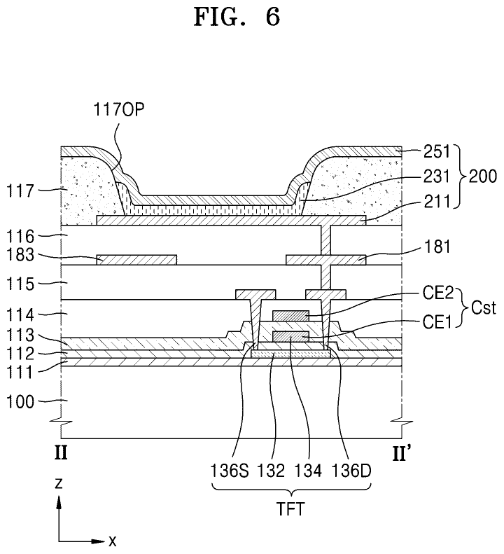

FIG. 5 is a partial top view schematically illustrating an arrangement of pixels according to an embodiment. FIG. 6 is a cross-sectional view schematically illustrating the display apparatus according to an embodiment, being the cross-sectional view along line II-II′ of FIG. 5.

The plurality of pixels arranged in the display area DA may include a first pixel PX1, a second pixel PX2, and a third pixel PX3. The first pixel PX1, second pixel PX2, and third pixel PX3 may be repeatedly arranged according to a certain pattern in the column and row direction. The first pixel PX1, the second pixel PX2, and the third pixel PX3 may include each of a pixel circuit and an organic light-emitting diode OLED electrically connected to the pixel circuit. The organic light-emitting diode OLED of each pixel may be arranged directly on a upper portion overlapping the pixel circuit, or may be offset from the pixel circuit to overlap the pixel circuit of a pixel in an adjacent row or column. The arrangement of pixels may be an arrangement of the organic light-emitting diode OLED in each of the first pixel PX1, second pixel PX2, and third pixel PX3, or an arrangement of a pixel electrode 211 configuring the organic light-emitting diode OLED.

In each row R1, R2, . . . , the pixel electrode 211 of the first pixel PX1, the pixel electrode 211 of the second pixel PX2, the pixel electrode 211 of the third pixel PX3, and the pixel electrode 211 of the second pixel PX2 may be spaced apart from each other and arranged alternately in a zigzag form. The pixel electrode 211 of the first pixel PX1 and the pixel electrode 211 of the third pixel PX3 may be spaced apart from each other and disposed alternately on an imaginary first straight line IL1 in the first direction (x-direction). The pixel electrode 211 of the second pixel PX2 are offset from the pixel electrode 211 of the first pixel PX1 and the pixel electrode 211 of the third pixel PX3 in a direction between the first direction (x-direction) and the second direction (y-direction) and may be repeatedly disposed on an imaginary second straight line IL2 in the first direction (x-direction).

In a first column C1, the pixel electrode 211 of the first pixel PX1 and the pixel electrode 211 of the third pixel PX3 are spaced apart from each other and may be alternately disposed on an imaginary third straight line IL3 in the second direction (y-direction). In a second column C2 adjacent to the first column C1, the pixel electrode 211 of the second pixel PX2 are mutually spaced apart and may be repeatedly disposed on an imaginary fourth straight line IL4 in the second direction (y-direction). In a third column C3 adjacent to the second column C2, contrary to the first column C1, the pixel electrode 211 of the third pixel PX3 and the pixel electrode 211 of the first pixel PX1 are mutually spaced apart and may be alternately disposed on an imaginary fifth straight line IL5 in the second direction (y-direction).

The pixel electrode 211 of the first pixel PX1, the pixel electrode 211 of the second pixel PX2, and the pixel electrode 211 of the third pixel PX3 may have different areas. In an embodiment, the pixel electrode 211 of the third pixel PX3 may have a larger area compared to the pixel electrode 211 of the neighboring first pixel PX1. Additionally, the pixel electrode 211 of the third pixel PX3 may have a larger area compared to the pixel electrode 211 of the neighboring second pixel PX2. The pixel electrode 211 of the second pixel PX2 may have a larger area compared to the pixel electrode 211 of the neighboring first pixel PX1. In some embodiments, the pixel electrode 211 of the third pixel PX3 may have the same area as the pixel electrode 211 of the first pixel PX1. The pixel electrode 211 may have the shape of a polygon such as a quadrilateral, an octagonal shape, a polygonal shape, etc., a circular shape, an oval shape, etc., and the polygonal shape may also include a shape with rounded vertices. As used herein, a rounded vertex refers not only to a shape in which the vertex is curved and rounded, but also to a shape in which the sharp vertex is gently shaved.

A pixel defining film 117 covers at least a portion of the pixel electrode 211 and may define a light-emitter EA of an organic light-emitting diode OLED. The light-emitter EA is an area arranged in an intermediate layer 231, which may be defined by an opening 117OP of the pixel defining film 117. The light-emitter EA may include a first light-emitter EA1, a second light-emitter EA2, and a third light-emitter EA3. The first pixel PX1 may include the first light-emitter EA1, the second pixel PX2 may include the second light-emitter EA2, and the third pixel PX3 may include the third light-emitter EA3. The light-emitter EA may have the shape of a polygon such as a quadrilateral, an octagonal shape, a polygonal shape, etc., and the polygonal shape may also include a shape with rounded vertices.

In an embodiment, the first pixel PX1 may be a red pixel that emits red light, the second pixel PX2 may be a blue pixel that emits blue light, and the third pixel PX3 may be a green pixel that emits green light. In some embodiments, the first pixel PX1 may be a red pixel, the second pixel PX2 may be a green pixel, and the third pixel PX3 may be a blue pixel.

Referring to FIG. 6, a buffer layer 111 formed to prevent an impurity from infiltrating into a semiconductor layer of the thin-film transistor may be disposed on the substrate 100.

The substrate 100 may be formed from various materials, such as glass, metal, or plastic, etc. According to an embodiment, the substrate 100 may be a flexible substrate, and may include a polymer resin such as, for example, polyethersulfone (PES), polyacrylate (PAR), polyetherimide (PEI), polyethyelenennapthalate (PEN), polyethyeleneterepthalate (PET), polyphenylenesulfide (PPS), polyallylate, polyimide (PI), polycarbonate (PC), or cellulose acetate propionate (CAP).

The buffer layer 111 may include an inorganic insulation material such as silicon nitride or silicon oxide, and may be single layer or multiple layers.

A thin-film transistor TFT, a capacitor Cst, and an organic light-emitting diode 200 electrically connected to the thin-film transistor TFT may be disposed over the substrate 100. When the organic light-emitting diode 200 is electrically connected to the thin-film transistor TFT, it may be understood that the pixel electrode 211 is electrically connected to the thin-film transistor TFT. The thin-film transistor TFT may be a first thin-film transistor T1 of FIG. 4A and FIG. 4B.

The thin-film transistor TFT may include a semiconductor layer 132, a gate electrode 134, a source electrode 136S, and a drain electrode 136D. The semiconductor layer 132 may include an oxide semiconductor material. The semiconductor layer 132 may include an amorphous silicon, polycrystalline silicon, or organic semiconductor material. The gate electrode 134 may be formed as a single layer or multiple layers of one or more of materials for example, aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), copper (Cu) taking into account adhesion to adjacent layers, surface flatness of the stacked layer, and processability, etc..

A gate insulation layer 112 including an inorganic material such as silicon oxide, silicon nitride, and/or silicon oxynitride, etc. may be disposed between the semiconductor layer 132 and the gate electrode 134. A first interlayer insulation layer 113 and a second interlayer insulation layer 114 including an inorganic material such as silicon oxide, silicon nitride, and/or silicon oxynitride, etc. may be arranged between the gate electrode 134 and the source electrode 136S and the drain electrode 136D. The source electrode 136S and the drain electrode 136D may each be electrically connected to the semiconductor layer 132 through contact holes formed in the gate insulation layer 112, the first interlayer insulation layer 113, and the second interlayer insulation layer 114.

The source electrode 136S and the drain electrode 136D may be formed as a single layer or multiple layers of one or more of the following materials, aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

The capacitor Cst includes a lower electrode CE1 and an upper electrode CE2 overlapping the first interlayer insulation layer 113. The capacitor Cst may overlap with the thin-film transistor TFT. In FIG. 6, the gate electrode 134 of the thin-film transistor TFT is shown to be the lower electrode CE1 of the capacitor Cst. According to some embodiments, the capacitor Cst may not overlap the thin-film transistor TFT. The capacitor Cst may be covered by the second interlayer insulation layer 114.

The pixel circuit including the thin-film transistor TFT and the capacitor Cst may be covered with a first insulation layer 115 and a second insulation layer 116. The first insulation layer 115 and the second insulation layer 116 are planarized insulation layers, which may be an organic insulation layer. The first insulation layer 115 and the second insulation layer 116 may include an organic insulation material such as a general purpose polymer such as polymethylmethacrylate (PMMA) or polystyrene (PS), a polymer derivative with a phenolic group, an acrylic-based polymer, an imide-based polymer, an aryl ether-based polymer, an amide-based polymer, a fluoro-based polymer, a p-xylene-based polymer, a vinyl alcohol-based polymer, and blends thereof, etc. In an embodiment, the first insulation layer 115 and the second insulation layer 116 may include polyimide.

A display element, for example the organic light-emitting diode 200, may be disposed on the second insulation layer 116. The organic light-emitting diode 200 may include the pixel electrode 211, the intermediate layer 231, and a counter electrode 251.

The pixel electrode 211 is disposed on the second insulation layer 116 and may be connected to the thin-film transistor TFT by a connection electrode 181 on the first insulation layer 115. Wiring 183, such as the data line DL and drive voltage line PL, may be disposed on the first insulation layer 115.

The pixel electrode 211 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In some embodiments, the pixel electrode 211 may include a reflective film including silver (Ag), magnesium (Mg), aluminum (Al), platinum (Pt), palladium (Pd), gold (Au), nickel (Ni), neodymium (Nd), iridium (Ir), chromium (Cr), or compounds thereof. In some embodiments, the pixel electrode 211 may further include a film formed of ITO, IZO, ZnO, or In₂O₃ above/below the aforementioned reflective film.

The pixel defining film 117 may be disposed on the second insulation layer 116. The pixel defining film 117 covers an edge of the pixel electrode 211 and may define a pixel by having the first opening 117OP through which a portion of the pixel electrode 211 is exposed. The pixel defining film 117 may serve to prevent arcing etc. from occurring at the edge of the pixel electrode 211 by increasing the distance between the edge of the pixel electrode 211 and the counter electrode 251. The pixel defining film 117 may be formed from an organic material such as, for example, polyimide (PI) or hexamethyldisiloxane (HMDSO), etc.

The intermediate layer 231 includes an emission layer. The emission layer may include a polymeric or low molecular weight organic material that emit light of a certain color. The emission layer may be arranged in the opening 117OP of the pixel defining film 117 to form the light-emitter EA. In an embodiment, the intermediate layer 231 may include a first function layer disposed below the emission layer and/or a second function layer disposed above the emission layer. The first function layer and/or the second function layer may also include a single layer across the plurality of pixel electrodes 211, or may also include a layer patterned to correspond to each of the plurality of pixel electrodes 211.

The first function layer may be a single layer or multiple layers. For example, when the first function layer is formed from a polymeric material, the first function layer may be a single-layer structure, a hole transport layer (HTL), formed from poly-(3,4)-ethylene-dihydroxy thiophene (PEDOT) or polyaniline (PANI). When the first function layer is formed from a low molecular weight material, the first function layer may include a hole injection layer (HIL) and a hole transport layer (HTL).

The second function layer is not always provided. For example, when the first function layer and the emission layer are formed from a polymeric material, it is desirable to form a second function layer to improve the properties of the organic light-emitting diode. The second function layer may be a single layer or multiple layers. The second function layer may include an electron transport layer (ETL) and/or an electron injection layer (EIL).

The counter electrode 251 is disposed to face the pixel electrode 211 with the intermediate layer 231 in between. The counter electrode 251 may be made of a low work-function conductive material. For example, the counter electrode 251 may include a (semi-) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof, etc. Alternatively, the counter electrode 251 may further include a layer such as ITO, IZO, ZnO, or In₂O₃ on top of the (semi-) transparent layer including the aforementioned material.

The counter electrode 251 may be disposed on top of the intermediate layer 231 and the pixel defining film 117. The counter electrode 251 may be integrally formed on the plurality of organic light-emitting diodes 200 in the display area DA to counter the plurality of pixel electrodes 211.

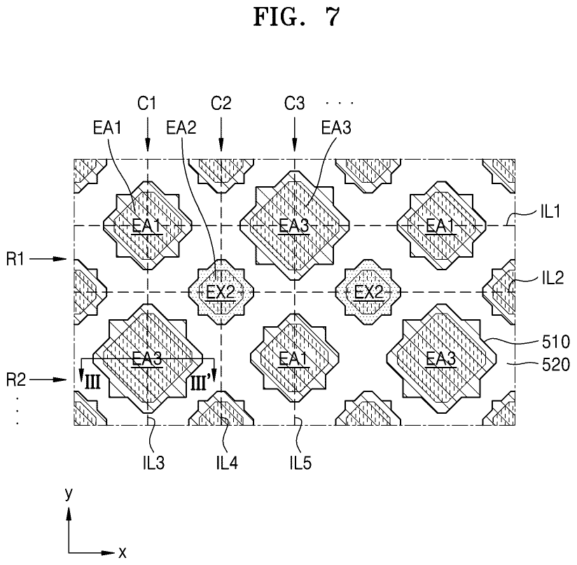

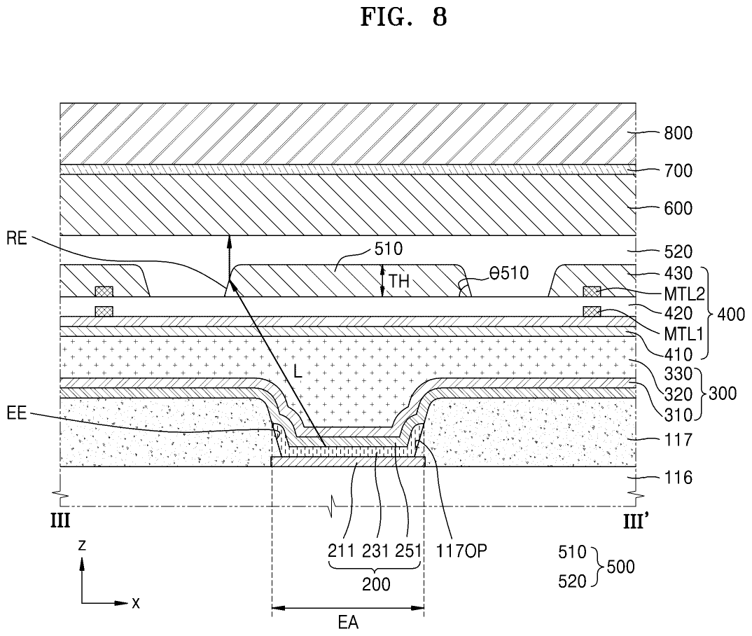

FIG. 7 is a top view schematically illustrating an arrangement of light-emitters in the display area according to an embodiment. FIG. 8 is a cross-sectional view schematically illustrating the display apparatus according to an embodiment, being the cross-sectional view along line III-III′ of FIG. 7. Hereinafter, the content described with reference to FIG. 5 and FIG. 6 will be omitted.

In an embodiment, an encapsulation layer 300 may be disposed on top of the counter electrode 251. The encapsulation layer 300 may serve to protect the organic light-emitting diode 200 from external moisture, oxygen, etc. The encapsulation layer 300 may have a multi-layer structure. The encapsulation layer 300 may include a first inorganic encapsulation layer 310, an organic encapsulation layer 320, and a second inorganic encapsulation layer 330. By forming the encapsulation layer 300 as a multi-layer structure, even if cracks occur within the encapsulation layer 300, the cracks may not connect between the first inorganic encapsulation layer 310 and the organic encapsulation layer 320 or between the organic encapsulation layer 320 and the second inorganic encapsulation layer 330, thereby preventing or minimizing the formation of a pathway for moisture or oxygen, etc. from the outside to infiltrate into the display area DA. According to some embodiments, the number of organic encapsulation layers and the number of inorganic encapsulation layers and the stacking order may be changed.

The first inorganic encapsulation layer 310 covers the counter electrode 251 and may include an inorganic insulation material of one or more of aluminum oxide, titanium oxide, tantalum oxide, hafnium oxide, zinc oxide, silicon oxide, silicon nitride, and silicon oxynitride. The first inorganic encapsulation layer 310 is formed along a structure beneath it, and thus may not have a flat upper surface.

The organic encapsulation layer 320 covers the first inorganic encapsulation layer 310 and may have sufficient thickness. The upper surface of the organic encapsulation layer 320 may be substantially flat across the display area DA. The organic encapsulation layer 320 may include polyethyleneterephthalate, polyethyelenennapthalate, polycarbonate, polyimide, polyethylene sulfonate, polyoxymethylene, polyarylate, hexamethyldisiloxane, an acrylic-based resin (for example, polymethylmethacrylate, polyacrylic acid, etc.), or any combination thereof.

The second inorganic encapsulation layer 330 covers the organic encapsulation layer 320 and may include one or more inorganic insulation materials such as aluminum oxide, titanium oxide, tantalum oxide, hafnium oxide, zinc oxide, silicon oxide, silicon nitride, silicon oxynitride. The second inorganic encapsulation layer 330 may extend outside of the organic encapsulation layer 320 and contact the first inorganic encapsulation layer 310 in the peripheral area PA, thereby preventing the organic encapsulation layer 320 from being exposed to the outside.

On the other hand, the process of forming the encapsulation layer 300 may damage the structures beneath it. For example, in the process of forming the first inorganic encapsulation layer 310, the layer directly beneath the forming first inorganic encapsulation layer 310 may be damaged. Therefore, at least one capping layer and/or protective layer may be disposed between the counter electrode 251 and the encapsulation layer 300 to prevent damage to the underlying structure during the process of forming the encapsulation layer 300. The capping layer and/or protective layer may include an inorganic material.

The input detection layer 400 may be disposed over the organic light-emitting diode 200, for example, over the encapsulation layer 300. The input detection layer 400 may acquire coordinate information according to an external input, for example a touch event of an object such as a finger or a stylus pen. The input detection layer 400 may include a sensing electrode and/or a trace line, etc. The input detection layer 400 may detect external inputs in a mutually capped or self-capped manner.

The input detection layer 400 may include a first conductive layer MTL1 and a second conductive layer MTL2, which may include the sensing electrode and/or the trace line, etc. A first touch insulation layer 410 may be disposed between the encapsulation layer 300 and the first conductive layer MTL1, and a second touch insulation layer 420 may be disposed between the first conductive layer MTL1 and the second conductive layer MTL2. A third touch insulation layer 430 may be disposed on top of the second conductive layer MTL2 and the second touch insulation layer 420.

The first conductive layer MTL1 and the second conductive layer MTL2 may include a conductive material. The conductive material may include molybdenum (Mo), aluminum (Al), copper (Cu), titanium (Ti), etc., and may be formed as multiple layers or a single layer including any of the above materials. In some embodiments, the first conductive layer MTL1 and the second conductive layer MTL2 may have a structure in which a titanium layer, an aluminum layer, and a titanium layer are sequentially stacked (Ti/Al/Ti).

The first touch insulation layer 410, the second touch insulation layer 420, and the third touch insulation layer 430 may include an inorganic insulation material and/or an organic insulation material. The inorganic insulation material may include silicon oxide, silicon oxynitride, silicon nitride, etc. The organic insulation material may include an acrylic-based, imide-based organic material.

The refractive layer 500 may be disposed over the organic light-emitting diode 200, for example, over the encapsulation layer 300. The refractive layer 500 may adjust the path of light emitted from the emission layer of the organic light-emitting diode 200 and may serve as a focusing lens. The refractive layer 500 may change the path of light emitted from the emission layer of the organic light-emitting diode 200 that is traveling in a lateral direction (for example, a direction other than the third direction (z-direction)) and allow the light to proceed in a third direction (z-direction) which is approximately forward.

The refractive layer 500 may include a first refractive layer 510 and a second refractive layer 520. An edge RE of the first refractive layer 510 may be patterned to surround the light-emitter EA. In other words, the first refractive layer 510 may be formed in a pattern to surround the light-emitter EA. The first refractive layer 510 may be disposed to overlap the light-emitter EA in the third direction (z-direction). The first refractive layer 510 may be disposed to cover the light-emitter EA. The first refractive layer 510 may be arranged in the same layer as the third touch insulation layer 430 and may include the same material. The thickness TH of the first refractive layer 510 in a direction perpendicular to the substrate 100 (for example, z-direction) may be at least about 1.5 μm but not more than about 5 μm.

The edge RE of the first refractive layer 510 may be formed to be inclined. In other words, the edge RE of the first refractive layer 510 may be provided as an incline. An angle θ510 formed by the edge RE of the first refractive layer 510 and the layer disposed below, e.g., in the x-y plane, may be at least about 30° but not more than about 85°. Since the second touch insulation layer 420 may be disposed underneath the first refractive layer 510, the angle θ510 formed by the edge RE of the first refractive layer 510 and the second touch insulation layer 420 disposed below may be at least about 30° but not more than about 85°.

The second refractive layer 520 may be disposed on the first refractive layer 510. The second refractive layer 520 may cover the first refractive layer 510, filling in between the patterns of the first refractive layer 510. In an embodiment, the second refractive layer 520 may be an adhesive layer disposed underneath the polarization layer 600. The adhesive layer may include at least one of an acrylate-based resin, a silicone-based resin, a urethane-based resin, an epoxy-based resin, a rubber-based resin, or a polyester-based resin, and may include one or more types within the same family of resins. The second refractive layer 520 disposed on the first refractive layer 510 may utilize the adhesive layer disposed underneath the polarization layer 600 rather than a separate high refractive flat layer, thereby reducing material or process costs.

A refractive index of the first refractive layer 510 may be greater than the refractive index of the second refractive layer 520. The difference between the refractive index of the first refractive layer 510 and the refractive index of the second refractive layer 520 may be at least about 0.04 but not more than about 1. In an embodiment, the refractive index of the first refractive layer 510 may be approximately about 1.45 to about 1.65. The refractive index of the second refractive layer 520 may be approximately about 1.4 to about 1.5.

In an embodiment, by including the first refractive layer 510 and the second refractive layer 520 arranged in the light-emitter EA, among the light emitted from the organic light-emitting diode 200, the light incident on the first refractive layer 510 is refracted at the interface between the first refractive layer 510 and the second refractive layer 520 and may be extracted in the third direction (z-direction).

In an embodiment, the polarization layer 600 may be disposed on the second refractive layer 520. The polarization layer 600 may transmit light emitted from the display elements of the display element layer DPL (see FIG. 2) only to light oscillating in the same direction as the polarization axis, and may absorb or reflect light oscillating in other directions. The polarization layer 600 may include a retarder and/or a polarizer. Additionally, the polarization layer 600 may include a black matrix and/or a color filter. Although not illustrated, the refractive layer 500 and the polarization layer 600 may be adhered by an adhesive, such as the optically clear adhesive (OCA).

The window 800 is disposed over the polarization layer 600, between which the adhesive layer 700, such as the optically clear adhesive (OCA), may be arranged.

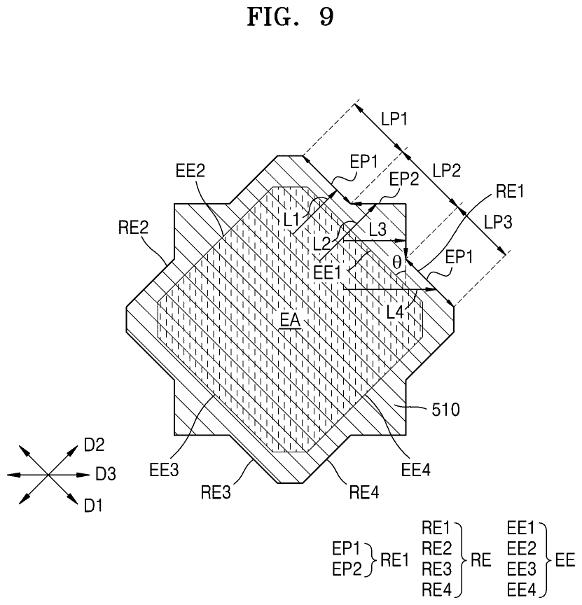

FIG. 9 is a top view schematically illustrating the placement relationship of a light-emitter EA and a first refractive layer 510 according to an embodiment.

In an embodiment, the light-emitter EA may have the shape of a polygon such as a quadrilateral, an octagonal shape, a polygonal shape, etc., and the polygonal shape may also include a shape with rounded vertices. As described above, as used herein, a rounded vertex refers not only to a shape in which the vertex is curved and rounded, but also to a shape in which the sharp vertex is gently shaved. In FIG. 9, for convenience of explanation, the light-emitter EA is described as having an octagonal shape (substantially, a shape in which the vertices of a square are cut into straight lines), but the embodiment is not limited thereto.

The light-emitter EA is an area in which an emission layer arranged inside the opening 117OP of the pixel defining film 117 is formed, and the edge EE of the light-emitter EA may refer to an edge of the emission layer.

Referring to FIG. 9, the edge EE of the light-emitter EA may include a first light-emitting edge EE1 and a third light-emitting edge EE3 extending in a first direction (D1 direction), and a second light-emitting edge EE2 and a fourth light-emitting edge EE4 extending in a second direction (D2 direction). The first through fourth light-emitting edges EE1, EE2, EE3, and EE4 may be connected to each other by a rounded vertex portion, such that the light-emitter EA may have a roughly quadrilateral shape.

The first refractive layer 510 may be arranged overlapping the light-emitter EA. The first refractive layer 510 may be arranged to surround the light-emitter EA. The edge RE of the first refractive layer 510 may be arranged to surround the edge EE of the light-emitter EA. The edge RE of the first refractive layer 510 may include a first refractive edge RE1 corresponding to the first light-emitting edge EE1, a second refractive edge RE2 corresponding to the second light-emitting edge EE2, a third refractive edge RE3 corresponding to the third light-emitting edge EE3, and a fourth refractive edge RE4 corresponding to the fourth light-emitting edge EE4.

Hereinafter, the description will be based on the first light-emitting edge EE1 and the corresponding first refractive edge RE1, however the same may be applied to the second light-emitting edge EE2 and the corresponding second refractive edge RE2, the third light-emitting edge EE3 and the corresponding third refractive edge RE3, and the fourth light-emitting edge EE4 and the corresponding fourth refractive edge RE4.

In an embodiment, the first refractive edge RE1 corresponding to the first light-emitting edge EE1 may include a first portion EP1 and a second portion EP2. The first portion EP1 may be a part of the first refractive edge RE1 that forms a first angle with the first light-emitting edge EE1 when viewed in a direction perpendicular to the substrate 100 (e.g., in the z-direction, see FIG. 2) (hereinafter, on a plane, e.g., the x-y plane, see FIG. 1), and the second portion EP2 may be a portion of the first refractive edge RE1 that forms an angle greater than the first angle with the first light-emitting edge EE1 on a plane.

As used herein, an angle that each of the first portion EP1 and the second portion EP2 of the first refractive edge RE1 forms with the first light-emitting edge EE1 refers to an acute angle that each of the first portion EP1 and the second portion EP2 forms with the first light-emitting edge EE1 on a plane.

Referring to FIG. 9, in an embodiment, the first portion EP1 is parallel to the first light-emitting edge EE1, and the second portion EP2 may not be parallel to the first light-emitting edge EE1. In other words, the first angle between the first portion EP1 and the first light-emitting edge EE1 is 0°, and an angle θ that the second portion EP2 forms with the first light-emitting edge EE1 may be greater than 0°. In an embodiment, the angle θ at which the second portion EP2 forms with the first light-emitting edge EE1 may be at least about 20° but not more than about 70°. The angle θ at which the second portion EP2 forms with the first light-emitting edge EE1 may be about 45°.

In an embodiment, on a plane, the first portion EP1 is parallel to the first light-emitting edge EE1 and the second portion EP2 may protrude in a direction perpendicular to the first light-emitting edge EE1. Referring to FIG. 9, the first portion EP1 may be shaped to extend in the first direction (D1 direction) and the second portion EP2 may be shaped to project in the second direction (D2 direction).

In an embodiment, the first refractive edge RE1 may be formed by connecting the first portion EP1, the second portion EP2, and the first portion EP1 in this order. When the first refractive edge RE1 includes a plurality of first portions EP1 spaced apart from each other, the length of the first portion EP1 refers to the total length LP1+LP3 of the first portion EP1, and the same is true for a length LP2 of the second portion EP2. In an embodiment, the length LP2 of the second portion EP2 may be at least about 0.2 times but not more than about 4 times the length LP1+LP3 of the first portion EP1. The length LP2 in the first direction (D1 direction) of the second portion EP2 may be at least about 0.2 times but not more than about 4 times the length LP1+LP3 in the first direction (D1 direction) of the first portion EP1.

When the organic light-emitting diode emits white light, the white characteristic observed from the front and the white characteristic observed from the side are different. White angle difference (WAD) is an item that evaluates the change of white characteristics according to the observation angle, and the level is evaluated by measuring the amount of luminance change and the amount of color coordinate change according to the observation angle compared to the front perpendicular to the screen. By including the first portion EP1 and the second portion EP2 forming different angles to the edge EE of the light-emitter EA on a plane, the edge RE of the first refractive layer 510 according to an embodiment may reduce the difference between the white characteristics observed from the front and the white characteristics observed from the side by altering the light path through the first refractive layer 510.

To explain specifically with reference to FIG. 9, a first light L1, a portion of the light emitted from the light-emitter EA in the second direction (D2 direction), may be incident perpendicularly to the edge RE of the first refractive layer 510, and a second light L2, the other portion, may be incident diagonally to the edge RE of the first refractive layer 510. A third light L3, a portion of the light emitted from the light-emitter EA in the third direction (D3 direction), may be diagonally incident on the edge RE of the first refractive layer 510, and a fourth light L4, the other portion, may be perpendicularly incident on the edge RE of the first refractive layer 510.

If the edge RE of the first refractive layer 510 is formed with only the first portion EP1, the first light L1 and the second light L2 are incident perpendicularly to the edge RE of the first refractive layer 510, and both the third light L3 and the fourth light L4 are incident diagonally to the edge RE of the first refractive layer 510.

On the other hand, according to an embodiment, the edge RE of the first refractive layer 510 includes the first portion EP1 and the second portion EP2 that have different angles from the edge EE of the light-emitter EA, so that light emitted from the light-emitter EA in a specific direction may be dispersed at various angles and enter the edge RE of the first refractive layer 510, thereby improving WAD characteristics.

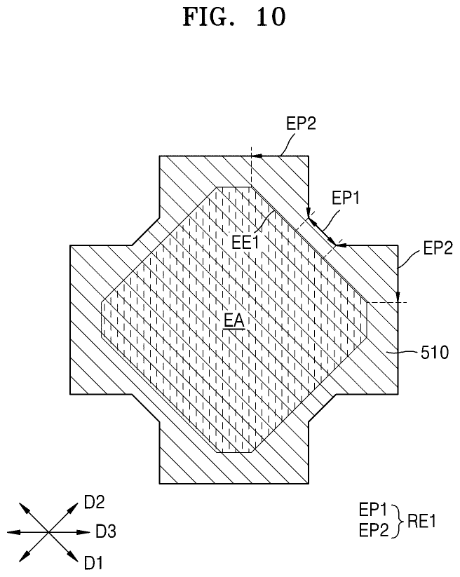

FIG. 10 to FIG. 14 are top views schematically illustrating an example placement relationship of the light-emitter EA and the first refractive layer 510 according to an embodiment. Hereinafter, the content described with reference to FIG. 8 and FIG. 9 will be omitted.

Referring to FIG. 10, the first refractive edge RE1 corresponding to the first light-emitting edge EE1 may include the first portion EP1 parallel to the first light-emitting edge EE1 and the second portion EP2 at about 45° to the first light-emitting edge EE1. Unlike the embodiment of FIG. 9 in which the first refractive edge RE1 is connected in the order of the first portion EP1, the second portion EP2, and the first portion EP1, the first refractive edge RE1 of FIG. 10 may be provided in the order of the second portion EP2, the first portion EP1, and the second portion EP2. That is, the first portion EP1 parallel to the first light-emitting edge EE1 may be located in the center of the first refractive edge RE1, and the second portion EP2 protruding from the first light-emitting edge EE1 may be located on either side of the first portion EP1. As such, the edge RE of the first refractive layer 510 according to an embodiment includes the first portion EP1 and the second portion EP2 forming different angles from the edge EE of the light-emitter EA, and the location, arrangement order, and arrangement ratio of the first portion EP1 and the second portion EP2 may be changed as needed, allowing for freedom of design.

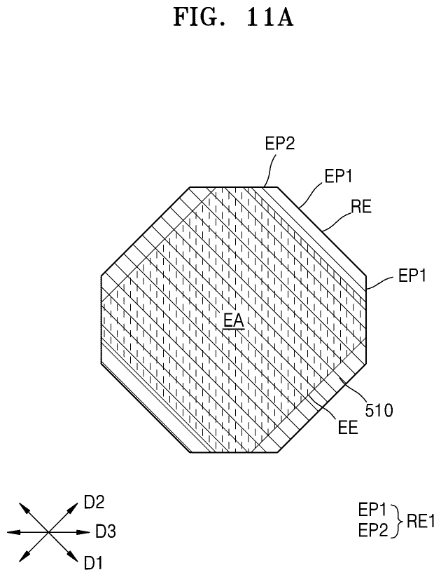

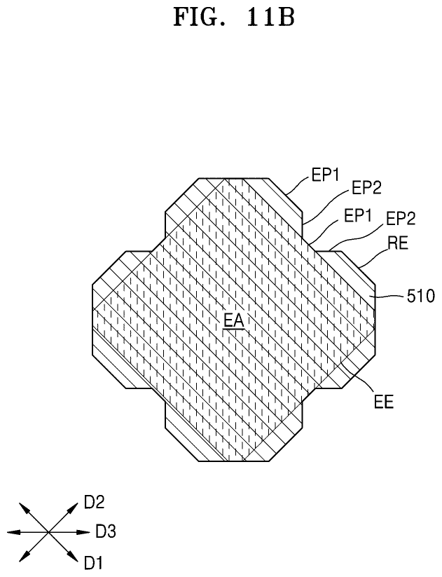

Referring to FIG. 11A and FIG. 11B, a portion of the edge RE of the first refractive layer 510 may overlap a portion of the edge EE of the light-emitter EA on a plane. In an embodiment, the rounded vertex portion of the edge EE of the light-emitter EA may coincide with the edge RE of the first refractive layer 510. In an embodiment, a portion of the edge RE of the first refractive layer 510 may overlap with each of a portion of the first light-emitting edge EE1, a portion of the second light-emitting edge EE2, a portion of the third light-emitting edge EE3, and a portion of the fourth light-emitting edge EE4 of the edge EE of the light-emitter EA. As a portion of the edge RE of the first refractive layer 510 is arranged to overlap with a portion of the edge EE of the light-emitter EA, the margin for arranging the first refractive layer 510 may be reduced and the spacing between the pixels may be reduced.

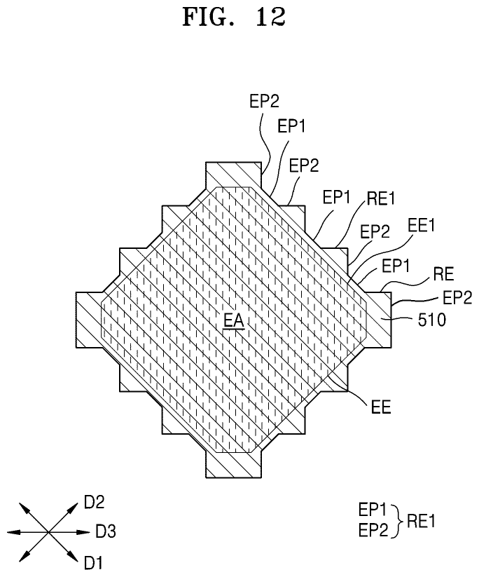

Referring to FIG. 12, the edge RE of the first refractive layer 510 may be provided with a first portion EP1 and a second portion EP2 alternately connected. The first refractive edge RE1 corresponding to the first light-emitting edge EE1 may be provided with a plurality of second portions EP2 and a plurality of first portions EP1 alternately connected. Since the second portion EP2 may have a shape that protrudes from the light-emitter EA, the first refractive edge RE1 may include a plurality of protruding second portions EP2. For example, as shown in FIG. 12, the first refractive edge RE1 may include four second portions EP2 and three first portions EP1 alternately connected. The embodiment is not limited to this, and the edge RE of the first refractive layer 510 may be provided with first portion EP1 and second portion EP2 repeatedly connected as needed.

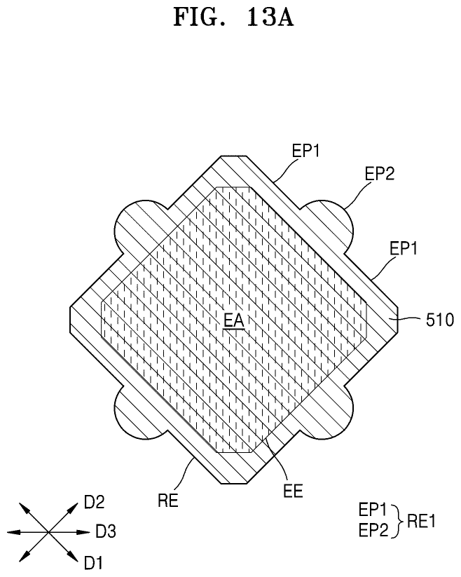

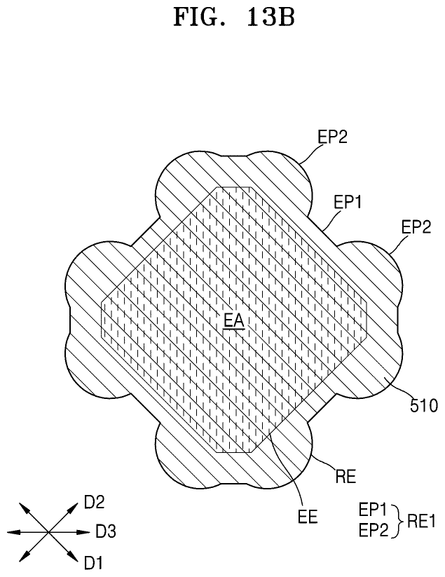

Referring to FIG. 13A and FIG. 13B, the second portion EP2 may be provided in the form of a curve on a plane. The angle formed by the edge EE of the second portion EP2 and the light-emitter EA may not be a specific value, but may refer to a range of angles larger than the first angle formed by the first portion EP1 and the edge EE of the light-emitter EA. In an embodiment, the angle formed the second portion EP2 and the edge EE of the light-emitter EA may be understood as the angle formed by a tangent line at the second portion EP2 and the edge EE of the light-emitter EA. When the second portion EP2 is provided in a curved shape, the space for arranging the first refractive layer 510 may be reduced, and it may be easy to implement a high-resolution display apparatus.

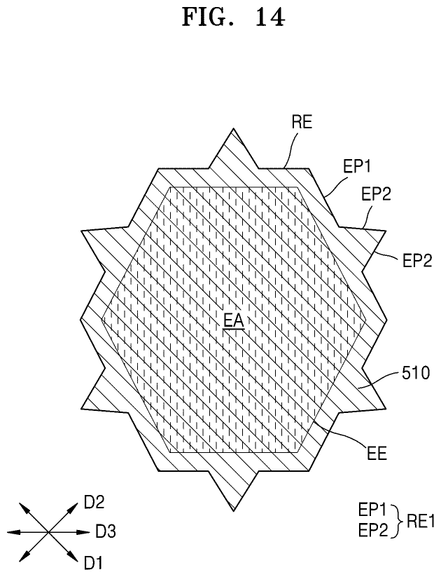

Referring to FIG. 14, the light-emitter EA may have a hexagonal shape on a plane. In the above-mentioned drawings, for the sake of simplicity, the light-emitter EA is described based on approximately having a quadrilateral shape, but the embodiments are not limited thereto. When the light-emitter EA is provided in an n-gonal shape, the edge EE of the light-emitter EA may include first to nth light-emitting edges (EE1, EE2, . . . EEN). The edge RE of the first refractive layer 510 may have first to nth refractive edges (RE1, RE2, . . . REn) corresponding to each light-emitting edge, and each refractive edge may include the first portion EP1 and the second portion EP2.

A display apparatus according to an embodiment includes the light-emitter EA, the first refractive layer 510 on the light-emitter EA, and the second refractive layer 520 covering the first refractive layer 510, and the edge RE of the first refractive layer 510 has the first portion EP1 and the second portion EP2, thereby providing a display apparatus with improved light emission efficiency and WAD characteristics.

The disclosure has thus been described with reference to embodiments shown in the drawings, which are only for example, and those skilled in the art will understand that various modifications and variations of the embodiments are possible therefrom. Therefore, the true technical scope of protection of the disclosure should be determined by the technical idea of the appended claims.

According to embodiments, it may be possible to provide a display apparatus with increased efficiency of light extracted from the display apparatus and emits light with an even luminance distribution even when the user's observation angle changes. However, such effects are for example, and the effects according to the embodiments will be described in more detail hereinafter.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a display element comprising a light-emitter that emits light;
a first refractive layer disposed on the display element; and
a second refractive layer covering the first refractive layer,
wherein an edge of the light-emitter comprises a first light-emitting edge extending in a first direction,
an edge of the first refractive layer comprises a first refractive edge corresponding to the first light-emitting edge, and
wherein the first refractive edge comprises a first portion forming a first angle with the first light-emitting edge on a plane, and a second portion forming a second angle greater than the first angle with the first light-emitting edge on the plane.

2. The display apparatus of claim 1,
wherein the edge of the first refractive layer surrounds the light-emitter.

3. The display apparatus of claim 1,
wherein the first light-emitting edge and the first portion are parallel on the plane.

4. The display apparatus of claim 3,
wherein the second angle is of at least about 20° but not more than about 70° on the plane.

5. The display apparatus of claim 1,
wherein the second portion is shaped to protrude in a second direction intersecting the first direction on the plane.

6. The display apparatus of claim 1,
wherein the first refractive edge has a form in which the first portion and the second portion are alternately connected.

7. The display apparatus of claim 1,
wherein a length in the first direction of the second portion is at least about 0.2 times but not more than about 4 times a length in the first direction of the first portion.

8. The display apparatus of claim 1,
wherein the first refractive layer overlaps at least partially with the light-emitter.

9. The display apparatus of claim 1,
wherein the first refractive layer has a refractive index greater than a refractive index of the second refractive layer.

10. The display apparatus of claim 1,
wherein a portion of the edge of the first refractive layer overlaps a portion of the edge of the light-emitter on the plane.

11. The display apparatus of claim 1,
wherein the second portion is in the form of a curve on the plane.

12. The display apparatus of claim 1,
wherein the first refractive layer has a thickness of at least about 1.5 μm but not more than about 5 μm.

13. The display apparatus of claim 1,
wherein the edge of the first refractive layer is provided with an incline forming an angle of at least about 30° but not more than about 85° with a layer disposed below.

14. The display apparatus of claim 1,
further comprising an encapsulation layer between the display element and the first refractive layer.

15. The display apparatus of claim 14,
further comprising an input detection layer disposed over the encapsulation layer and comprising a conductive layer and a touch insulation layer covering the conductive layer,
wherein the touch insulation layer and the first refractive layer are arranged on a same layer.

16. A display apparatus comprising:
a display element comprising a light-emitter that emits light;
an encapsulation layer covering the display element;
a first refractive layer disposed over the encapsulation layer, an edge of the first refractive layer surrounding the light-emitter;
a second refractive layer covering the first refractive layer, and
wherein the edge of the first refractive layer comprises a first portion parallel to an edge of the light-emitter on a plane, and a second portion protruding in a direction perpendicular to the edge of the light-emitter on the plane.

17. The display apparatus of claim 16,
wherein a refractive index of the first refractive layer is at least 0.04 greater than a refractive index of the second refractive layer.

18. The display apparatus of claim 16,
wherein the edge of the first refractive layer has a form in which the first portion and the second portion are alternately connected.

19. The display apparatus of claim 16,
wherein the second portion is in the form of a curve on the plane.

20. The display apparatus of claim 16,
wherein the edge of the first refractive layer is provided with an incline forming an angle of at least about 30° but not more than about 85° with a layer disposed below.
